(19) United States
(12) Patent Application Publication
(10) Pub. No.: US 2025/0316316 A1
(43) Pub. Date: Oct. 9, 2025

(54) SEMICONDUCTOR DEVICE

(71) Applicant: SK hynix Inc., Icheon-si Gyeonggi-do (KR)

(72) Inventors: Eun Seok CHOI, Icheon-si Gyeonggi-do (KR); Hyun Seung YOO, Icheon-si Gyeonggi-do (KR); Eun Mee KWON, Icheon-si Gyeonggi-do (KR)

(73) Assignee: SK hynix Inc., Icheon-si Gyeonggi-do (KR)

(21) Appl. No.: 18/772,931

(22) Filed: Jul. 15, 2024

(30) Foreign Application Priority Data
Apr. 8, 2024 (KR) 10-2024-0047534

(51) Int. Cl. G11C 16/30; G11C 16/04; H01L 23/00; H01L 25/065; H01L 25/18; H10B 80/00

(52) U.S. Cl. CPC G11C 16/30; G11C 16/0483; H01L 24/08; H01L 25/0657; H01L 25/18; H10B 80/00; H01L 2224/08145; H01L 2924/1431; H01L 2924/14511

(57) ABSTRACT

A semiconductor device includes: one or more first source switches configured to control a connection between a global source line and a first local source line; one or more second source switches configured to control a connection between the global source line and a second local source line; a first memory block configured to operate using a first source voltage supplied through the first local source line; a second memory block configured to operate using a second source voltage supplied through the second local source line; a first source pass transistor configured to control the first source switch in response to a first block select signal; and a second source pass transistor configured to control the second source switch in response to a second block select signal.

### CROSS-REFERENCE TO RELATED APPLICATION

The present application claims priority under 35 U.S.C. § 119(a) to Korean Patent Application No. 10-2024-0047534 filed in the Korean Intellectual Property Office on Apr. 8, 2024, which application is incorporated herein by reference in its entirety.

### BACKGROUND

### 1. Technical Field

Embodiments of the present disclosure generally relate to an electronic device, and more particularly, to an electronic device including a semiconductor device.

### 2. Related Art

The degree of integration of a semiconductor device is mainly determined by an area occupied by a unit memory cell. Recently, as the improvement in the degree of integration of a semiconductor device for forming memory cells in a single layer on a substrate reaches a limit, a three-dimensional semiconductor device for stacking memory cells on a substrate has been proposed. Furthermore, in order to improve the operational reliability of such a semiconductor device, various structures and manufacturing methods have been developed.

### SUMMARY

In an embodiment, a semiconductor device may include: one or more first source switches configured to control a connection between a global source line and a first local source line; one or more second source switches configured to control a connection between the global source line and a second local source line; a first memory block configured to operate using a first source voltage supplied through the first local source line; a second memory block configured to operate using a second source voltage supplied through the second local source line; a first source pass transistor configured to control the first source switch in response to a first block select signal; and a second source pass transistor configured to control the second source switch in response to a second block select signal.

In an embodiment, a semiconductor device may include: one or more first source switches configured to control a connection between a global source line and a first local source line; one or more second source switches configured to control a connection between the global source line and a second local source line; a memory block including a first sub-memory block configured to operate using a first source voltage supplied through the first local source line and a second sub-memory block configured to operate using a second source voltage supplied through the second local source line; a first source pass transistor configured to control the first source switch in response to a block select signal; and a second source pass transistor configured to control the second source switch in response to the block select signal.

In an embodiment, a semiconductor device may include: a gate structure including gate lines and insulating layers that are alternately stacked; a local source line located on the gate structure; source switches located on the local source line and configured to control a connection between a global source line and the local source line; and a source pass transistor configured to control the source switches.

### BRIEF DESCRIPTION OF THE DRAWINGS

FIG. 1 is a block diagram illustrating the configuration of a semiconductor device in accordance with an embodiment.

FIG. 2A is a block diagram illustrating the configuration of a semiconductor device in accordance with an embodiment, and FIG. 2B is a circuit diagram in accordance with an embodiment.

FIGS. 3A and 3B are diagrams illustrating the structure of a semiconductor device in accordance with an embodiment.

FIGS. 4A and 4B are circuit diagrams of a semiconductor device in accordance with an embodiment.

FIGS. 5A and 5B are diagrams illustrating the structure of a semiconductor device in accordance with an embodiment.

FIG. 6 is a diagram for describing the structure of a semiconductor device in accordance with an embodiment.

FIG. 7 is a diagram for describing the structure of a semiconductor device in accordance with an embodiment.

FIG. 8 is a configuration diagram of a semiconductor device according to an embodiment of the present disclosure.

FIG. 9 is a configuration diagram of a semiconductor device according to an embodiment of the present disclosure.

### DETAILED DESCRIPTION

Various embodiments are directed to a semiconductor device having a stable structure and improved characteristics. It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. In the description of the present disclosure, the terms “first” and “second” may be used to describe various components, but the components are not limited by the terms. The terms may be used to distinguish one component from another component. For example, a first component may be called a second component and a second component may be called a first component without departing from the scope of the present disclosure.

By stacking memory cells in three dimensions in an embodiment, it is possible to improve the degree of integration of a semiconductor device. It is also possible, in an embodiment, to provide a semiconductor device having a stable structure and improved reliability.

Hereafter, embodiments in accordance with the technical spirit of the present disclosure will be described with reference to the accompanying drawings.

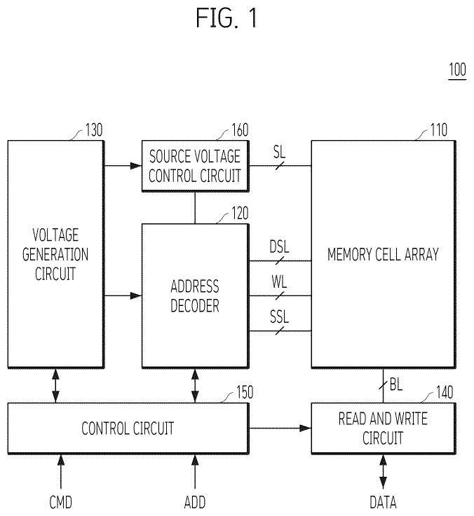

FIG. 1 is a block diagram illustrating the configuration of a semiconductor device in accordance with an embodiment.

Referring to FIG. 1, the semiconductor device 100 may include a memory cell array 110, an address decoder 120, a voltage generation circuit 130, a read and write circuit 140, a control circuit 150, and a source voltage control circuit 160.

The memory cell array 110 may include memory cells. As an example, the memory cell array 110 may include memory blocks, each of which may include pages. Here, the memory block may be a unit of an erase operation, and the page may be a unit of a read operation. The memory cell array 110 may be connected to the address decoder 120 through row lines such as a source select line SSL, a word line WL, and a drain select line DSL. The memory cell array 110 may be connected to the read and write circuit 140 through a column line such as a bit line BL.

The control circuit 150 may receive a command CMD and an address ADD from a controller. The control circuit 150 may generate control signals so as to perform internal operations such as a program operation, a read operation, and an erase operation according to the received command CMD. The control circuit 150 may output the control signals to the voltage generation circuit 130, the address decoder 120, and the read and write circuit 140.

The voltage generation circuit 130 may generate internal voltages of various voltage levels for performing the internal operations, and may provide the generated internal voltages to the address decoder 120 and the source voltage control circuit 160. The internal voltage may be an operation voltage for performing the program operation, the read operation, the erase operation, or the like. As an example, the internal voltage may be a source voltage to be supplied to the local source line SL.

As an example, the voltage generation circuit 130 may generate a program voltage, a pass voltage, a source voltage, a bit line voltage, or the like, for performing the program operation. The voltage generation circuit 130 may generate a read voltage, a pass voltage, a source voltage, a bit line voltage, or the like, for performing the read operation. The read operation may be a verify operation for verifying the program operation or the erase operation. The voltage generation circuit 130 may generate an erase voltage, a gate induced drain leakage (GIDL) voltage, a source voltage, or the like, for performing the erase operation.

The address decoder 120 may activate the source select line SSL, the word line WL, or the drain select line DSL according to the address. The address decoder 120 may transmit a voltage level of a global line to a local line. The source voltage control circuit 160 may activate the local source line according to the address. The source voltage control circuit 160 may transmit a voltage level of a global source line to the local source line.

The read and write circuit 140 may be connected to the memory cell array 110 through the bit lines BL. During the program operation, the read and write circuit 140 may operate as a writer driver and may input data that is to be stored in the memory cell array 110. During the read or verify operation, the read and write circuit 140 may operate as a sense amplifier and may output data stored in the memory cell array 110.

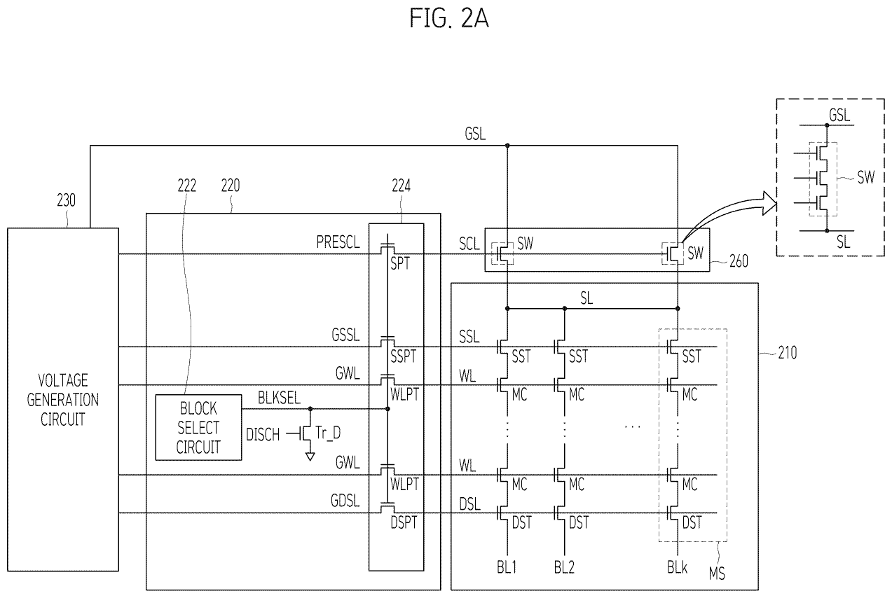

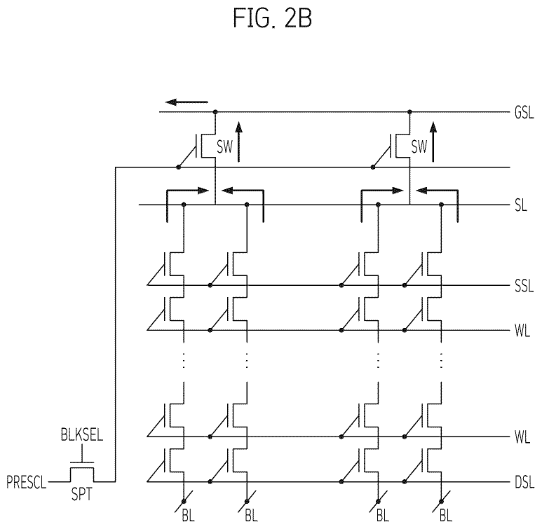

FIG. 2A is a block diagram illustrating the configuration of a semiconductor device in accordance with an embodiment, and FIG. 2B is a circuit diagram in accordance with an embodiment. Hereinafter, the content overlapping with the previously described content may be omitted.

Referring to FIG. 2A, the semiconductor device 200 may include a memory cell array 210, an address decoder 220, a voltage generation circuit 230, and a source voltage control circuit 260.

The memory cell array 210 may include a plurality of memory blocks, each of which may include memory strings MS. The memory strings MS may be connected between bit lines BL1 to BLk and a local source line SL. Here, k may be an integer of 2 or more. Each memory string MS may include at least one drain select transistor DST, a plurality of memory cells MC, and at least one source select transistor SST.

Gate electrodes of the memory cells MC may be connected to word lines WL. A source select line SSL may be connected to a gate electrode of the source select transistor SST. A connection between the memory string MS and the local source line SL may be controlled by the source select line SSL. When the source select transistor SST is turned on, the memory string MS and the local source line SL may be connected to each other. A drain select line DSL may be connected to a gate electrode of the drain select transistor DST. A connection between the memory string MS and the bit lines BL1 to BLk may be controlled by the drain select line DSL. When the drain select transistor DST is turned on, the memory string MS and the bit line BL may be connected to each other.

The voltage generation circuit 230 may generate operation voltages required for program operations, read operations, and erase operations of the memory cells, and may transmit the generated operation voltages to global lines. As an example, during the program operation, the voltage generation circuit 230 may transmit a program voltage or a pass voltage to a global word line GWL and transmit a source voltage to a global source line GSL. During the read operation, the voltage generation circuit 230 may transmit a read voltage or a pass voltage to the global word line GWL and transmit a source voltage to the global source line GSL. During the erase operation, the voltage generation circuit 230 may transmit a GIDL voltage to at least one of a global drain select line GDSL and a global source select line GSSL, transmit a ground voltage to the global word line GWL, and transmit an erase voltage to the global source line GSL.

The address decoder 220 may include a block select circuit 222 and a pass circuit 224. The block select circuit 222 may generate a block select signal BLKSEL in response to an address, and may transmit the generated block select signal BLKSEL to the pass circuit 224. A discharge transistor Tr_D may discharge a line through which the block select signal BLKSEL is transmitted, in response to a discharge signal DISCH.

The pass circuit 224 may include pass transistors for controlling connections between the global lines and local lines. The pass circuit 224 may include at least one source select pass transistor SSPT, a plurality of word line pass transistors WLPT, and at least one drain select pass transistor DSPT. The source select pass transistor SSPT may control a connection between the global source select line GSSL and the source select line SSL. The word line pass transistor WLPT may control a connection between the global word line GWL and the word line WL. The drain select pass transistor DSPT may control a connection between the global drain select line GDSL and the drain select line DSL.

The pass circuit 224 may be controlled by the block select signal BLKSEL. The pass circuit 224 may operate in response to the block select signal BLKSEL of the block select circuit 222. The block select signal BLKSEL may be applied to a gate electrode of the pass transistor, and when the block select signal BLKSEL is activated, the pass transistor may be turned on, and the global line and the local line may be electrically connected to each other. When the block select signal BLKSEL is activated, the global source select line GSSL and the source select line SSL may be connected to each other. When the block select signal BLKSEL is activated, the global word line GWL and the word line WL may be connected to each other. When the block select signal BLKSEL is activated, the global drain select line GDSL and the drain select line DSL may be connected to each other.

The pass circuit 224 may further include at least one source pass transistor SPT. The source pass transistor SPT may control a connection between a pre-source control line PRESCL and a source control line SCL. When the block select signal BLKSEL is activated, the source pass transistor SPT may be turned on, and the pre-source control line PRESCL and the source control line SCL may be connected to each other.

The source voltage control circuit 260 may control a connection between the global source line GSL and the local source line SL. The source voltage control circuit 260 may include one or more source switches SW. The source switch SW may be controlled by the source pass transistor SPT. When the source pass transistor SPT is turned on, a source control signal may be applied to a gate electrode of the source switch SW through the source control line SCL. The source control signal may be a turn-on voltage, and the source switch SW is turned on, such that the global source line GSL and the local source line SL may be connected to each other. Accordingly, the source voltage may be applied to the local source line SL.

The source voltage control circuit 260 may include a plurality of source switches SW, and may supply the source voltage to different locations of the local source line SL. The source switch SW may include one or more transistors connected to each other in series. As an example, the source switch SW may be a high-voltage transistor.

During a read/verify operation, the local source line SL may be pre-charged and/or discharged through the source switch SW. Referring to FIG. 2B, a cell current flowing through the memory string MS may flow to the global source line GSL through the source switch SW. When the number of source switches SW included in the source voltage control circuit 260 is increased, the number of memory strings MS sharing one source switch SW with each other may be reduced. Accordingly, in an embodiment, the cell current may be quickly discharged during the read/verify operation, and a cell distribution may be improved by reducing a voltage drop (potential drop) of the local source line SL.

According to the configuration described above, the source switch SW may be controlled using the source pass transistor SPT included in the pass circuit 224. By controlling the connection between the global source line GSL and the local source line SL through the source switch SW, it is possible to apply the source voltage to the local source line SL. Here, the local source line SL may be separated by memory block units or sub-memory block units. Accordingly, the source voltage may be applied in memory block units or sub-memory block units.

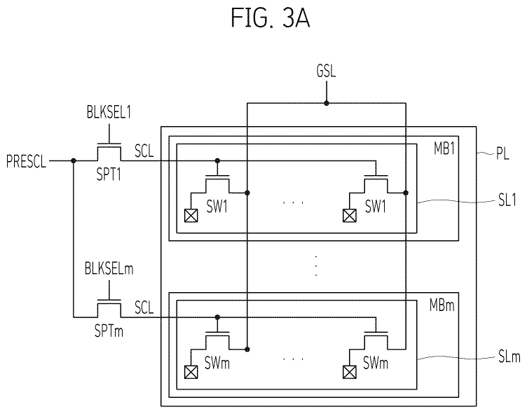

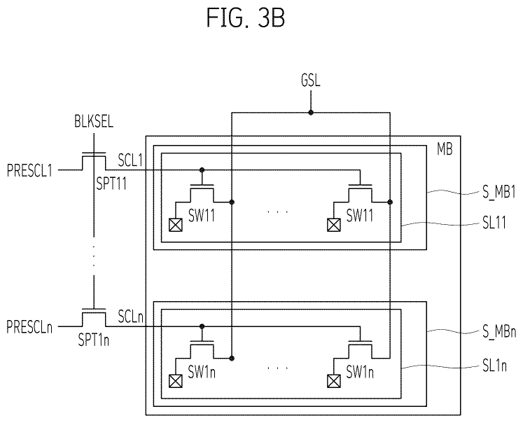

FIGS. 3A and 3B are diagrams illustrating the structure of a semiconductor device in accordance with an embodiment.

Referring to FIG. 3A, the semiconductor device may include a global source line GSL, local source lines SL1 to SLm, a pre-source control line PRESCL, source control lines SCL, source pass transistors SPT1 to SPTm, source switches SW1 to SWm, and a memory plane PL. Here, m may be an integer of 2 or more. The memory plane PL may include a plurality of memory blocks MB1 to MBm. The local source lines SL1 to SLm may be separated by memory block units.

The memory blocks MB1 to MBm may be connected to the local source lines SL1 to SLm, respectively. The memory blocks MB1 to MBm may operate using source voltages supplied through the local source lines SL1 to SLm. One or more source switches SW1 to SWm may be connected to the local source lines SL1 to SLm, respectively. The source voltage may be supplied to different locations of the local source lines SL1 to SLm by a plurality of source switches SW1 to SWm.

The source pass transistors SPT1 to SPTm may control connections between the pre-source control line PRESCL and the source control lines SCL. The source switches SW1 to SWm may be controlled by the source pass transistors SPT1 to SPTm, respectively, and may control connections between the global source line GSL and local source lines SL1 to SLm.

The source pass transistors SPT1 to SPTm may operate in response to block select signals BLKSEL1 to BLKSELm. The source pass transistors SPT1 to SPTm may be included in different pass circuits, and may be controlled by different block select signals BLKSEL1 to BLKSELm. As an example, when a first block select signal BLKSEL1 is activated, a first source pass transistor SPT1 may be turned on, and a turn-on voltage may be transmitted to the source switches SW1. When the source switches SW1 are turned on, the global source line GSL and a first local source line SL1 may be electrically connected to each other, and a source voltage of the global source line GSL may be transmitted to the first local source line SL1. When an m-th block select signal BLKSELm is activated, an m-th source pass transistor SPTm may be turned on, and a turn-on voltage may be transmitted to the source switches SWm. When the source switches SWm are turned on, the global source line GSL and an m-th local source line SLm may be electrically connected to each other, and the source voltage of the global source line GSL may be transmitted to the m-th local source line SLm.

Referring to FIG. 3B, the semiconductor device may include a global source line GSL, local source lines SL11 to SL1n, pre-source control lines PRESCL1 to PRESCLn, source control lines SCL1 to SCLn, source pass transistors SPT11 to SPT1n, source switches SW11 to SW1n, and a memory block MB. Here, n may be an integer of 2 or more. The memory block MB may include a plurality of sub-memory blocks S_MB1 to S_MBn. The local source lines SL11 to SL1n may be separated by sub-memory block units.

The sub-memory blocks S_MB1 to S_MBn may be connected to the local source lines SL11 to SL1n, respectively. The sub-memory blocks S_MB1 to S_MBn may operate using source voltages supplied through the local source lines SL11 to SL1n. One or more source switches SW11 to SW1n may be connected to the local source lines SL11 to SL1n, respectively. The source voltage may be supplied to different locations of the local source lines SL11 to SL1n by a plurality of source switches SW11 to SW1n.

The source pass transistors SPT11 to SPT1n may control the source switches SW11 to SW1n in response to a block select signal BLKSEL. The source pass transistors SPT11 to SPT1n may be included in the same pass circuit, and may be controlled by the same block select signal BLKSEL. A first source pass transistor SPT11 may control a connection between a first pre-source control line PRESCL1 and a first source control line SCL1. An n-th source pass transistor SPT1n may control a connection between an n-th pre-source control line PRESCLn and an n-th source control line SCLn.

When the block select signal BLKSEL is activated, a source control signal of the first pre-source control line PRESCL1 may be applied to a gate electrode of a first source switch SW11. When the source control signal is a turn-on voltage, a source voltage of the global source line GSL may be transmitted to a first local source line SL11. When the block select signal BLKSEL is activated, a source control signal of the n-th pre-source control line PRESCL1 may be applied to a gate electrode of an n-th source switch SW1n. When the source control signal is a turn-off voltage, the source voltage of the global source line GSL might not be transmitted to an n-th local source line SL1n. Through this, the source switch SW11 of a selected first sub-memory block S_MB1 may be turned on and the source switch SW1n of an unselected n-th sub-memory block may be turned off. Accordingly, an operation may be controlled in sub-memory block units.

According to the configuration described above, the connection between the global source line GSL and the local source line SL may be controlled through the source pass transistor SPT and the source switch SW. Accordingly, the same source voltage might not be applied to the entire memory plane PL. The source voltage may be applied to the selected memory block or the selected sub-memory block, and the unselected memory block or the unselected sub-memory block may be floated or grounded.

The local source lines SL1 to SLm may be separated by memory block units or the local source lines SL11 to SL1n may be separated by sub-memory block units. Through this, the source voltages may be applied in memory block units or sub-memory block units. Source voltages of different levels may be applied to the selected local source line and the unselected local source line. Accordingly, in an embodiment, source capacitance may be reduced, operation current consumption may be reduced, and operation characteristics may be improved.

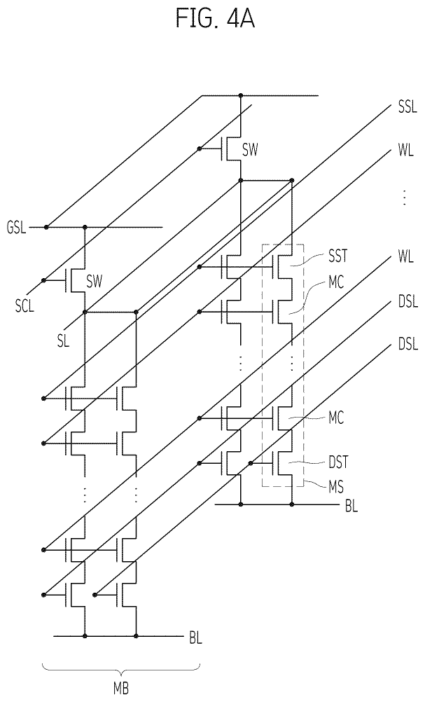

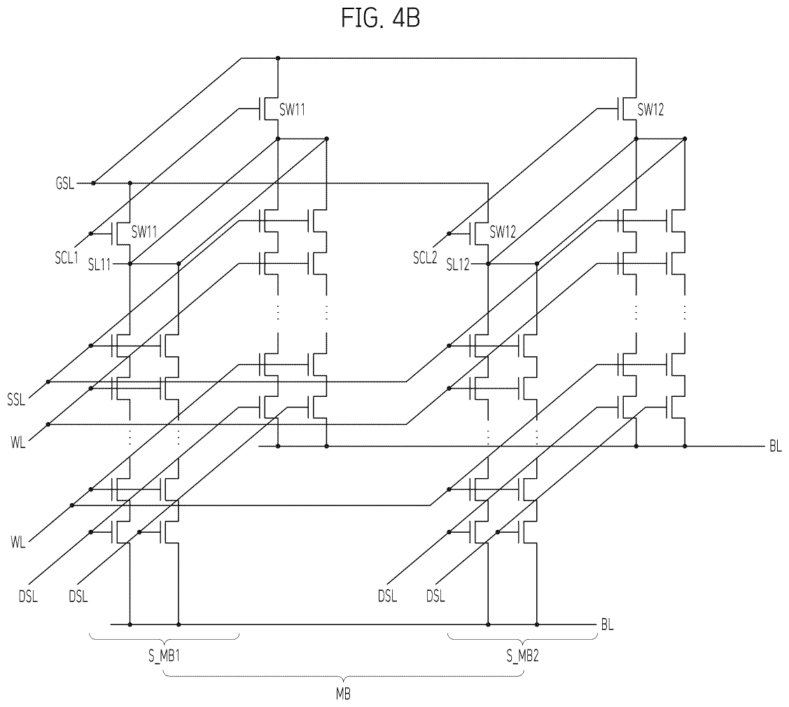

FIGS. 4A and 4B are circuit diagrams of a semiconductor device in accordance with an embodiment. Hereinafter, the content overlapping with the previously described content may be omitted.

Referring to FIG. 4A, a memory block MB may include a plurality of memory strings MS, which may be connected between bit lines BL and a local source line SL.

Each memory string MS may include at least one drain select transistor DST, a plurality of memory cells MC, and at least one source select transistor SST connected to each other in series. In addition, each memory string MS may further include at least one dummy memory cell connected between the drain select transistor DST and the memory cells MC and/or between the source select transistor SST and the memory cells MC.

Gate electrodes of the memory cells MC may be connected to word lines WL. Word line voltages (program voltages, pass voltages, read voltages, etc.) required for driving may be applied to the respective word lines WL. Gate electrodes of the drain select transistors

DST may be connected to a drain select line DSL. Gate electrodes of the source select transistors SST may be connected to a source select line SSL.

Drain select transistors DST arranged in the same row may be connected to the same drain select line DSL. Drain select transistors DST arranged in different rows may be connected to different drain select lines DSL. Memory cells MC of the same level may be connected to the same word line WL. Source select transistors SST of the same level may be connected to the same source select line SSL. The local source line SL may be separated by memory block MB units, and an erase operation may be performed in memory block units.

One or more source switches SW may be connected between a global source line GSL and the local source line SL. Gate electrodes of the source switches SW may be connected to a source control line SCL. Accordingly, by controlling the source switch SW, it is possible to connect the global source line GSL and the local source line SL to each other and it is possible to apply a source voltage to the local source line SL or discharge the local source line SL.

During a read operation, a current flows from the plurality of memory strings MS to the local source line SL. When a plurality of source switches SW are connected to one local source line SL, in an embodiment, the local source line SL may be discharged through the plurality of source switches SW, and thus, operation characteristics may be improved.

Referring to FIG. 4B, a memory block MB may include a first sub-memory block S_MB1 and a second sub-memory block S_MB2. A first local source line SL11 of the first sub-memory block S_MB1 and a second local source line SL12 of the second sub-memory block S_MB2 may be separated from each other. A plurality of first source switches SW11 may be connected to the first local source line SL11, and source control signals may be applied to the first source switches SW11 through a first source control line SCL1. A plurality of second source switches SW12 may be connected to the second local source line SL12, and source control signals may be applied to the second source switches SW12 through a second source control line SCL2.

A connection between a global source line GSL and the first local source line SL11 may be controlled by the first source switches SW11, and a connection between the global source line GSL and the second local source line SL12 may be controlled by the second source switches SW12. Accordingly, the first local source line SL11 and the second local source line SL12 may be individually controlled, and an erase operation may be performed in sub-memory block units. As an example, a source control signal of a level higher than an erase voltage may be applied through the first source control line SCL1, and a source control signal of a level lower than the erase voltage may be applied through the second source control line SCL2. Through this, the erase operation may be selectively performed on the first sub-memory block S_MB1.

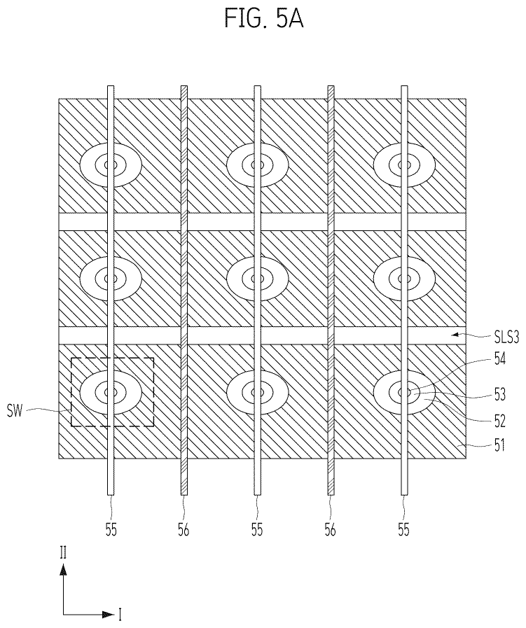

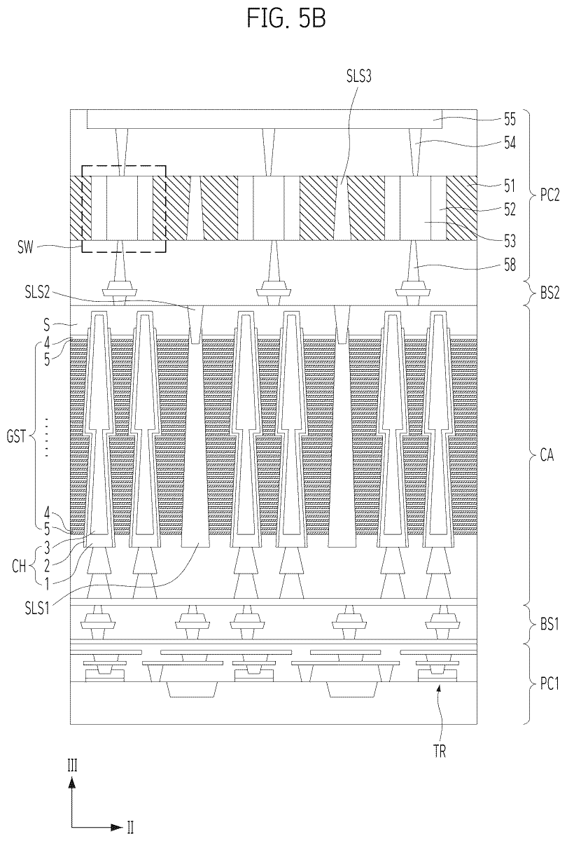

FIGS. 5A and 5B are diagrams illustrating the structure of a semiconductor device in accordance with an embodiment. Hereinafter, the content overlapping with the previously described content may be omitted.

Referring to FIGS. 5A and 5B, the semiconductor device may include a first peripheral circuit PC1, a first bonding structure BS1, a memory cell array CA, a second bonding structure BS2, and a second peripheral circuit PC2. Here, the first peripheral circuit PC1, the memory cell array CA, and the second peripheral circuit PC2 may be individually manufactured using separate wafers, and may be connected to each other through a wafer bonding process.

Through the first bonding structure BS1, the first peripheral circuit PC1 and the memory cell array CA may be bonded to each other and be electrically connected to each other. Through the second bonding structure BS2, the second peripheral circuit PC2 and the memory cell array CA may be bonded to each other and be electrically connected to each other. A page buffer, a row decoder, a logic circuit, and the like, may be distributed and disposed in the first peripheral circuit PC1 and the second peripheral circuit PC2. As an example, the first peripheral circuit PC1 may include a transistor TR.

The memory cell array CA may include a gate structure GST, a source structure S, a channel structure CH, a first slit structure SLS1, and a second slit structure SLS2. The gate structure GST may include gate lines 5 and insulating layers 4 that are alternately stacked. The source structure S may be located on the gate structure GST, and may be patterned in memory block units or sub-memory block units. Here, the source structure S may correspond to a local source line.

For reference, when an erase operation is performed by a gate induced drain leakage (GIDL) method, a material of the source structure S may be selected to generate a sufficient amount of holes using a source select transistor SST. As an example, the source structure S may include polysilicon doped with a high concentration of N-type impurities. As an example, the source structure S may be an N-type polysilicon layer including a material having a low energy band gap, such as germanium (Ge). As an example, the source structure S may be an N-type polysilicon layer, and may include a material having a low energy band gap, such as germanium (Ge), in a portion adjacent to the source select transistor SST.

The channel structure CH may extend into the source structure S through the gate structure GST. The channel structure CH may include a channel layer 1 connected to the source structure S, a memory layer 2 surrounding the channel layer 1, and an insulating core 3 located in the channel layer 1. A memory cell MC, a source select transistor SST, or a drain select transistor DST may be located in a region where the channel structure CH and the gate lines 5 intersect each other. One channel structure CH may correspond to one memory string.

The first slit structure SLS1 may extend through the gate structure GST, and may separate the gate structure GST in memory block units or sub-memory block units. The second slit structure SLS2 may extend through the source structure S, and may separate the source structure S in memory block units or sub-memory block units. The source structure S and the second slit structure SLS2 may be formed after the first peripheral circuit PC1 and the memory cell array CA are bonded to each other.

The second peripheral circuit PC2 may include a source voltage control circuit. Source control lines 51 may be located on the second bonding structure BS2. The source control lines 51 may extend in a first direction I, and may be separated from each other by a third slit structure SLS3. As an example, the source control lines 51 may be separated by memory block units or sub-memory block units. The first peripheral circuit PC1 may include a pass circuit, and the source control lines 51 may be electrically connected to the first peripheral circuit PC1.

Channel layers 53 may extend through the source control lines 51, and source switches SW may be located in regions where the channel layers 53 and the source control lines 51 intersect each other. The channel layers 53 may each include epitaxial silicon or polysilicon. Although not illustrated in FIGS. 5A and 5B, an insulating core may be formed in the channel layer 53. The channel layers 53 may be doped with impurities in order to change threshold voltages of the source switches SW. Insulating spacers 52 may surround sidewalls of the channel layers 53.

A lower portion of the channel layer 53 may be connected to the second bonding structure BS2 through a contact via 58, and may be electrically connected to the source structure S through the second bonding structure BS2. An upper portion of the channel layer 53 may be electrically connected to a first wiring line 55 through a contact via 54. The contact via 54 and the first wiring line 55 may be formed after the second peripheral circuit PC2 and the memory cell array CA are bonded to each other.

The first wiring lines 55 and second wiring lines 56 may be located on the source control lines 51. The first wiring lines 55 and the second wiring lines 56 may be alternately arranged along the first direction I, and may extend along a second direction II. In an embodiment, the first wiring line 55 may be a wiring line for transmitting a source voltage, and the second wiring line 56 may be a wiring line for transmitting an internal operation voltage. The first wiring line 55 may correspond to a global source line GSL.

According to various embodiments of the structure described above, connections between the first wiring lines 55 and the source structure S may be controlled through the source switches SW, and the source voltages of the first wiring lines 55 may be transmitted to the source structure S. In addition, a plurality of source switches SW may be connected to one source structure S. The number of memory strings sharing the source switch SW with each other may be adjusted by adjusting an interval between the source switches SW or an interval between the first wiring lines 55. In various embodiments, the number of memory strings processed by each source switch SW may be reduced by densely arranging the source switches SW.

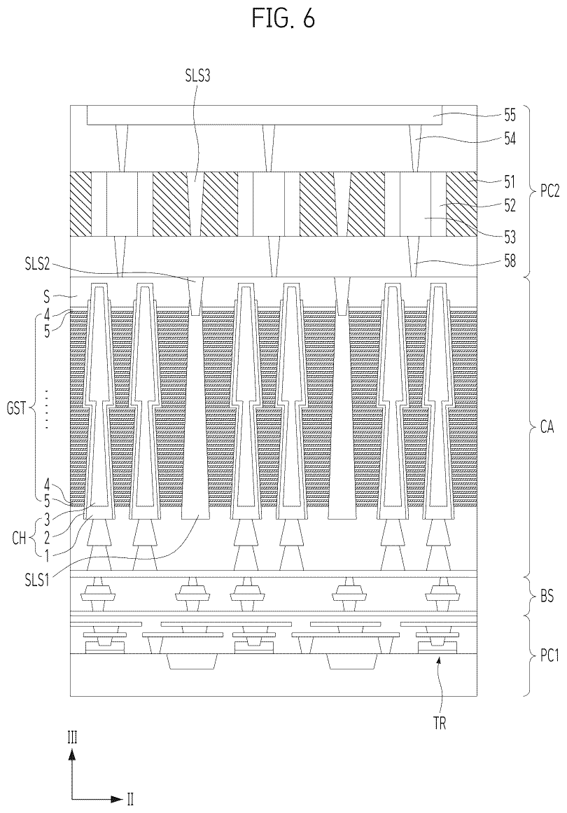

FIG. 6 is a diagram for describing the structure of a semiconductor device in accordance with an embodiment. Hereinafter, the content overlapping with the previously described content may be omitted.

Referring to FIG. 6, a memory cell array CA and a second peripheral circuit PC2 may be connected to each other without a bonding structure. After a first peripheral circuit PC1 and the memory cell array CA are connected to each other through a bonding process, a source structure S and a second slit structure SLS2 may be formed. Subsequently, a contact via 58, a source control line 51, an insulating spacer 52, a channel layer 53, a contact via 54, and a first wiring line 55 may be formed on the source structure S.

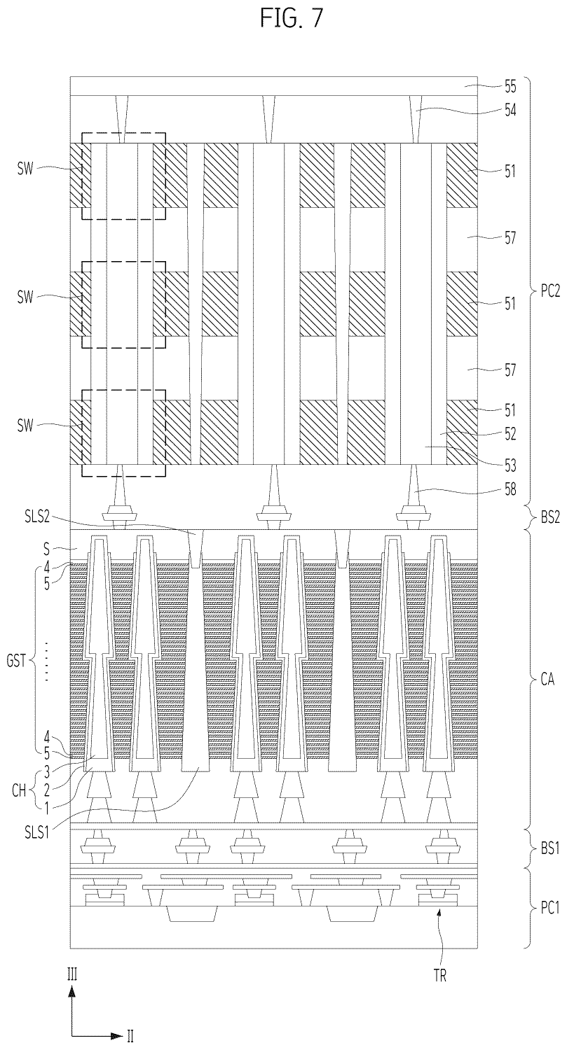

FIG. 7 is a diagram for describing the structure of a semiconductor device in accordance with an embodiment. Hereinafter, the content overlapping with the previously described content may be omitted.

Referring to FIG. 7, source control lines 51 may be stacked in multiple layers on a source structure S. A plurality of source control lines 51 and a plurality of insulating layers 57 may be alternately stacked. A channel layer 53 may extend through the source control lines 51 and the insulating layers 57.

According to such a structure, source switches SW may be stacked between the source structure S (i.e., local source line) and a first wiring line 55 (i.e., global source line). As an example, a plurality of source switches SW may be connected to each other in series between a local source line and a global source line. Accordingly, during an erase operation, erase voltages may be transmitted through the plurality of source switches SW. When the erase operation is performed in sub-memory block units, the transmission of the erase voltage to an unselected local source line may be blocked through the plurality of source switches SW.

Other structures may be the same as or similar to those of an embodiment described above with reference to FIG. 5B or FIG. 6.

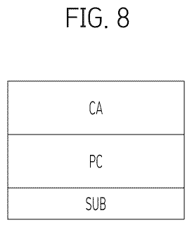

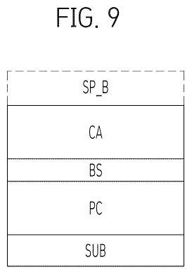

The structure and the manufacturing method according to the above-described embodiments may be applied to semiconductor devices of various structures. FIGS. 8 and 9 illustrate a schematic configuration of a semiconductor device to which the above-described embodiments are applicable.

FIG. 8 is a configuration diagram of a semiconductor device according to an embodiment of the present disclosure.

Referring to FIG. 8, the semiconductor device may include a substrate SUB, a peripheral circuit PC, and a memory cell array CA. Here, the peripheral circuit PC and the memory cell array CA may be formed on the same substrate.

The substrate SUB may be made of or include a semiconductor material. In an embodiment, the semiconductor material may include at least one of a group IV semiconductor, a group III-V compound semiconductor, and a group II-VI compound semiconductor. Here, the group IV semiconductor may include single crystal silicon Si, polycrystalline silicon, germanium Ge, or silicon germanium SiGe. The group III-V compound semiconductor may include GaAs, GaN, GaP, GaAsP, GaInAsP, AlAs, AlGa, InP, InSb, or InGaAs. The group II-VI compound semiconductor may include ZnS, ZnO, or CdS.

The substrate SUB may include a dielectric layer. The substrate SUB may be a silicon-on-insulator (SOI) substrate, a germanium-on-insulator (GeOI) substrate, or a glass substrate. The substrate SUB may include an organic material. In an embodiment, the substrate SUB may include graphene.

The substrate SUB may be a bulk wafer or an epitaxial layer grown in a selective epitaxial growth (SEG) method. The substrate SUB may be a layer formed in a metal induced lateral crystallization (MILC) method and may partially include metal. The substrate SUB may have a single crystalline, polycrystalline, or amorphous state. The substrate SUB may include an impurity of group II, group III, group IV, group V, or group VI. In an embodiment, the substrate SUB may include an n-well region doped with an n-type impurity and/or a p-well region doped with a p-type impurity.

The peripheral circuit PC may be disposed between the substrate SUB and the memory cell array CA. The peripheral circuit PC may include a row decoder, a column decoder, a page buffer, a logic circuit, a control circuit, a sense amplifier, an input/output circuit, and the like. In an embodiment, the peripheral circuit PC may include an NMOS transistor, a PMOS transistor, a resistor, a capacitor, and the like. The peripheral circuit PC may further include an interconnection structure. The interconnection structure may be used as a path for transferring an operation voltage, and may include a contact plug, a line, and the like.

The memory cell array CA may include memory cells. In an embodiment, the memory cell array CA may include memory strings connected between a source line and a bit line, and each memory string may include stacked memory cells. In an embodiment, the memory cell array CA may include memory cells connected between a word line and a bit line. The memory cell array CA may further include an interconnection structure.

FIG. 9 is a configuration diagram of a semiconductor device according to an embodiment of the present disclosure.

Referring to FIG. 9, the semiconductor device may include a substrate SUB, a peripheral circuit PC, a bonding structure BS, and a memory cell array CA. Here, the peripheral circuit PC and the memory cell array CA may be respectively formed on separate substrates and then bonded. The semiconductor device may further include a support base SP_B.

The substrate SUB may be used as a support in a process of forming the peripheral circuit PC. The support base SP_B may be used as a support in a process of forming the memory cell array CA. In an embodiment, after respectively manufacturing a first wafer including the memory cell array CA and a second wafer including the peripheral circuit PC, the first wafer and the second wafer may be electrically connected by the bonding structure BS. After bonding, at least a portion of the support base SP_B of the first wafer may be removed. The support base SP_B may be completely removed or may partially remain on the memory cell array CA.

The support base SP_B may be a semiconductor substrate, an insulating substrate, a silicon-on-insulator (SOI) substrate, a germanium-on-insulator (GeOI) substrate, or the like. The support base SP_B may be a bulk wafer, an epitaxial layer grown in a selective epitaxial growth (SEG) method, or a layer formed in a metal induced lateral crystallization (MILC) method. The support base SP_B may have a single crystalline, polycrystalline, or amorphous state. The support base SP_B may include an impurity of group II, group III, group IV, group V, or group VI.

The bonding structure BS may be for connecting the memory cell array CA and the peripheral circuit PC. In an embodiment, the memory cell array CA and the peripheral circuit PC may be bonded in a wafer-on-wafer bonding method, a chip-on-wafer bonding method, a chip-on-chip bonding method, or the like. The bonding structure BS may include a bonding pad, a bonding layer, a bonding interface, and the like. The bonding pad may include a metal such as copper and aluminum, and/or an alloy. The bonding interface may include a non-metal-non-metal interface, a metal-metal interface, or the like. The memory cell array CA and the peripheral circuit PC may be electrically connected by the bonding structure BS.

For reference, an interconnection structure included in the memory cell array CA and/or the peripheral circuit PC may be directly connected without a bonding pad. In an embodiment, a bonding layer included in the memory cell array CA and a bonding layer included in the peripheral circuit PC may be bonded to form a bonding interface, and the interconnection structure included in the memory cell array CA and the interconnection structure included in the peripheral circuit PC may be directly connected. Through this, contact plugs, lines, and the like formed on different wafers may be electrically connected without a separate bonding pad.

Other configurations may be equal or similar to those described above with reference to FIG. 8.

Meanwhile, the semiconductor device may have a structure in which the embodiments described above with reference to FIGS. 8 and 9 are combined or may have a partially modified structure. In the embodiment described with reference to FIGS. 8 and 9, positions of the memory cell array CA and the peripheral circuit PC may be changed. At least one memory cell array CA and/or at least one peripheral circuit PC may be additionally bonded to the embodiment described with reference to FIG. 8. In an embodiment, a portion of the peripheral circuitry PC may be disposed in the memory cell array CA.

Although embodiments according to the technical idea of the present disclosure have been described above with reference to the accompanying drawings, this is only for explaining the embodiments according to the concept of the present disclosure, and the present disclosure is not limited to the above embodiments. Various types of substitutions, modifications, changes, and combinations for the embodiments may be made by those skilled in the art, to which the present disclosure pertains, without departing from the technical idea of the present disclosure defined in the following claims, and it should be construed that these substitutions, modifications, changes, and combinations belong to the scope of the present disclosure.

What is claimed is:

1. A semiconductor device comprising:
one or more first source switches configured to control a connection between a global source line and a first local source line;
one or more second source switches configured to control a connection between the global source line and a second local source line;
a first memory block configured to operate using a first source voltage supplied through the first local source line;
a second memory block configured to operate using a second source voltage supplied through the second local source line;
a first source pass transistor configured to control the first source switch in response to a first block select signal; and
a second source pass transistor configured to control the second source switch in response to a second block select signal.

2. The semiconductor device of claim 1, further comprising a voltage generation circuit configured to generate the first source voltage and the second source voltage and to supply the first source voltage and the second source voltage to the global source line.

3. The semiconductor device of claim 1, wherein the one or more first source switches include a plurality of first source switches coupled to the first local source line at different locations, and the first source voltage is supplied to the different locations of the first local source line through the plurality of first source switches.

4. The semiconductor device of claim 1, wherein the first source switch includes one or more transistors connected to each other in series between the global source line and the first local source line.

5. The semiconductor device of claim 1, wherein during a read operation, the first local source line is pre-charged or discharged through the one or more first source switches.

6. The semiconductor device of claim 1, further comprising:
a global drain select line; and
a drain select pass transistor configured to control a connection between the global drain select line and a drain select line of the first memory block.

7. The semiconductor device of claim 1, further comprising:
global word lines;
word line pass transistors configured to control connections between the global word lines and word lines of the first memory block.

8. The semiconductor device of claim 1, further comprising:
a global source select line; and
a source select pass transistor configured to control a connection between the global source select line and a source select line of the first memory block.

9. A semiconductor device comprising:
one or more first source switches configured to control a connection between a global source line and a first local source line;
one or more second source switches configured to control a connection between the global source line and a second local source line;
a memory block including a first sub-memory block configured to operate using a first source voltage supplied through the first local source line and a second sub-memory block configured to operate using a second source voltage supplied through the second local source line;
a first source pass transistor configured to control the first source switch in response to a block select signal; and
a second source pass transistor configured to control the second source switch in response to the block select signal.

10. The semiconductor device of claim 9, further comprising a voltage generation circuit configured to generate the first source voltage and the second source voltage and to supply the first source voltage and the second source voltage to the global source line.

11. The semiconductor device of claim 9, wherein the one or more first source switches include a plurality of first source switches coupled to the first local source line at different locations, and the first source voltage is supplied to the different locations of the first local source line through the plurality of first source switches.

12. The semiconductor device of claim 9, wherein the one or more second source switches include a plurality of second source switches coupled to the second local source line at different locations, and the second source voltage is supplied to the different locations of the second local source line through the plurality of second source switches.

13. The semiconductor device of claim 9, wherein the first source switch includes one or more transistors connected to each other in series between the global source line and the first local source line.

14. The semiconductor device of claim 9, wherein during a read operation, the first local source line is pre-charged or discharged through the one or more first source switches.

15. A semiconductor device comprising:
a gate structure including gate lines and insulating layers that are alternately stacked;
a local source line located on the gate structure;
source switches located on the local source line and configured to control a connection between a global source line and the local source line; and
a source pass transistor configured to control the source switches.

16. The semiconductor device of claim 15, further comprising:
a peripheral circuit; and
a first bonding structure located between the peripheral circuit and the gate structure.

17. The semiconductor device of claim 15, further comprising a second bonding structure electrically connecting the source switches and the local source line to each other.

18. The semiconductor device of claim 15, wherein each of the source switches includes transistors stacked on the local source line.
